(19) United States
(12) Patent Application Publication
(10) Pub. No.: US 2025/0105534 A1
(43) Pub. Date: Mar. 27, 2025

(54) TERMINAL STRUCTURE

(71) Applicant: ADVANCED-CONNECTEK INC., New Taipei City (TW)

(72) Inventors: Shu-Fen Wang, New Taipei City (TW); Kuan-Lin Chen, New Taipei City (TW)

(21) Appl. No.: 18/644,097

(22) Filed: Apr. 24, 2024

(30) Foreign Application Priority Data
Sep. 27, 2023 (TW) 112210460

(51) Int. Cl. H01R 12/58; H01R 4/48; H01R 11/05; H01R 12/70; H01R 13/426; H01R 13/502

(52) U.S. Cl. CPC H01R 12/585; H01R 4/48; H01R 11/05; H01R 12/7023; H01R 13/426; H01R 13/502

(57) ABSTRACT

A terminal structure includes a terminal body, a locking means formed on at least one face of the terminal body, an insertion unit extending from a first end of the terminal body, and a holding mechanism extending from a second end of the terminal body. The insertion unit is mounted on a circuit board. The circuit board defines multiple conducting holes. The insertion unit is inserted into and locked in one of the conducting holes of the circuit board. The holding mechanism includes two opposite clamping arms and a clamping space defined between the two clamping arms. An electronic element is held by the holding mechanism. The electronic element has multiple lead legs. One of the lead legs of the electronic element is clamped between the two clamping arms and held in the clamping space.

### BACKGROUND OF THE INVENTION

### Field of the Invention

The present invention relates to a terminal and, more particularly, to a terminal structure.

### Description of the Related Art

A conventional surface mount technology (SMT) is widely used in the combined process of electronic components and printed circuit boards (PCB). The assembly and welding method of the SMT mainly uses a screen printer to print conductive material, such as solder paste, on the surface of a pad of the printed circuit board, and then uses a mount to place surface mount devices (SMD), such as resistors, capacitors, inductors, diodes, transistors, and integrated circuits (IC), on the solder pads. Finally, the method uses a hot air reflow process to accomplish the procedure. At present, various surface mount devices mostly use adhesion methods to attach the conductive material to the surface mount devices. Alternatively, a screen is used for full-surface printing so that the surface mount devices are bonded on the circuit board effectively by the use of large-area conductive material, to optimizes the conductive contact. Such a technology can be applied to miniaturized and lightweight electronic products. When the technical functions are increased, more electronic components are required. Currently, most of the electronic components used in automobiles are welded to the circuit board using the above-mentioned conventional surface mount technology. However, the circuit board includes too many complicated electronic components, so that the soldering work is more difficult, and the working time is increased. In addition, assembly of the electronic components is complicated and difficult.

### BRIEF SUMMARY OF THE INVENTION

The primary objective of the present invention is to provide a terminal structure that is assembled quickly and exactly.

In accordance with the present invention, there is provided a terminal structure comprising a terminal body, a locking means formed on at least one face of the terminal body, an insertion unit extending from a first end of the terminal body, and a holding mechanism extending from a second end of the terminal body. The insertion unit is mounted on a circuit board. The circuit board defines multiple conducting holes. The insertion unit is inserted into and locked in one of the conducting holes of the circuit board. The holding mechanism includes two opposite clamping arms and a clamping space defined between the two clamping arms. An electronic element is held by the holding mechanism. The electronic element has multiple lead legs. One of the lead legs of the electronic element is clamped between the two clamping arms and held in the clamping space.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a terminal structure in accordance with the preferred embodiment of the present invention.

FIG. 2 is a schematic front operational view showing the terminal structure assembled with an electronic element.

FIG. 3 is a schematic front view showing the terminal structure assembled with a fixture.

FIG. 4 is a schematic front view showing the terminal structure assembled with a housing.

FIG. 5 is a schematic front cross-sectional view showing the terminal structure assembled with a circuit board.

### DETAILED DESCRIPTION OF THE INVENTION

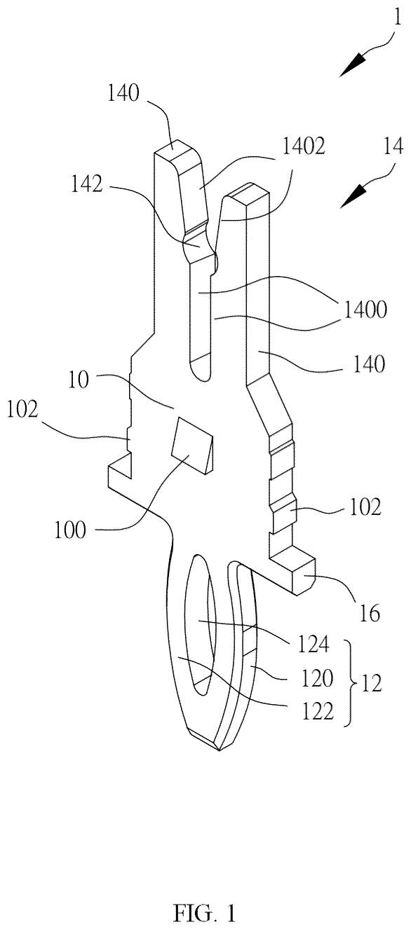

Referring to FIGS. 1-5, a terminal structure 1 in accordance with the preferred embodiment of the present invention comprises a terminal body 10, a locking means 100 formed on at least one face of the terminal body 10, an insertion unit 12 extending from a first end of the terminal body 10, and a holding mechanism 14 extending from a second end of the terminal body 10.

The insertion unit 12 is mounted on a circuit board 3. The circuit board 3 defines multiple conducting holes 30. The insertion unit 12 is inserted into and locked in one of the conducting holes 30 of the circuit board 3. The holding mechanism 14 includes two opposite clamping arms 140 and a clamping space 142 defined between the two clamping arms 140. An electronic element 2 is held by the holding mechanism 14. The electronic element 2 has multiple lead (or guide) legs 20. One of the lead legs 20 of the electronic element 2 is clamped between the two clamping arms 140 and held in the clamping space 142.

In the preferred embodiment of the present invention, a stop means (or an abutment) 16 is defined between the terminal body 10 and the insertion unit 12.

In the preferred embodiment of the present invention, the insertion unit 12 includes a first press side 120, a second press side 122 having two ends connecting two ends of the first press side 120, and an internal space (or inward pressing space or contraction space) 124 defined between the first press side 120 and the second press side 122.

In the preferred embodiment of the present invention, the terminal body 10 has two opposite sides. Each of the two sides of the terminal body 10 defines multiple interference means 102.

In the preferred embodiment of the present invention, each of the two clamping arms 140 defines a first side wall 1400 and a second side wall 1402. The first side wall 1400 of each of the two clamping arms 140 is located between the terminal body 10 and a first end of the clamping space 142. The second side wall 1402 of each of the two clamping arms 140 is an inclined face situated at a second end of the clamping space 142.

In the preferred embodiment of the present invention, the first side walls 1400 of the two clamping arms 140 are parallel with each other, with a constant distance defined between the first side walls 1400 of the two clamping arms 140.

In the preferred embodiment of the present invention, the second side walls 1402 of the two clamping arms 140 gradually diverge (or expand) forward from the clamping space 142.

In the preferred embodiment of the present invention, a fixture 4 defines multiple slots 40. The terminal body 10 is inserted into one of the slots 40 of the fixture 4. Each of the interference means 102 is locked in one of the slots 40 of the fixture 4.

In the preferred embodiment of the present invention, a housing 5 defines a mounting portion 50. The terminal structure 1 and the electronic element 2 are assembled and received in the mounting portion 50 of the housing 5 after the terminal structure 1 is locked on the electronic element 2. The fixture 4 is secured in the mounting portion 50 of the housing 5.

In practice, when the electronic element 2 is to be clamped by the terminal structure 1, the second side wall 1402 of each of the two clamping arms 140 is an inclined face to guide one of the lead legs 20 of the electronic element 2 to the clamping space 142. Then, the terminal structure 1 is pushed forcibly relative to the electronic element 2 so that one of the lead legs 20 of the electronic element 2 is inserted into and locked in the clamping space 142. In such a manner, the distance between the first side walls 1400 of the two clamping arms 140 has a constant value to enhance the pressing force of the two clamping arms 140 applied on one of the lead legs 20 of the electronic element 2, so that one of the lead legs 20 of the electronic element 2 is clamped in the clamping space 142 steadily to prevent detachment due to an external force.

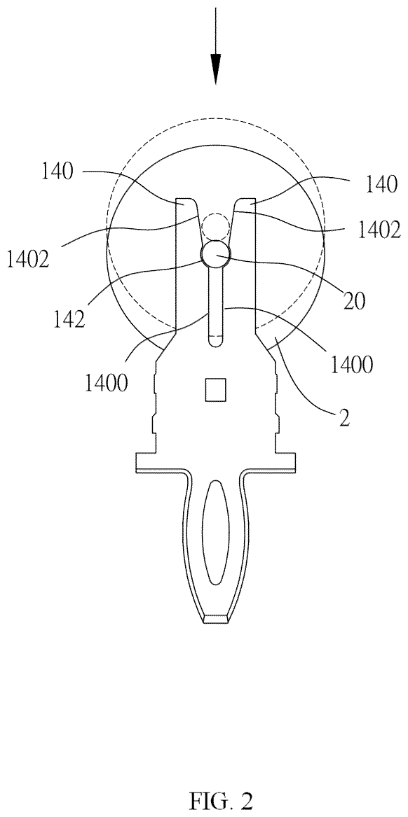

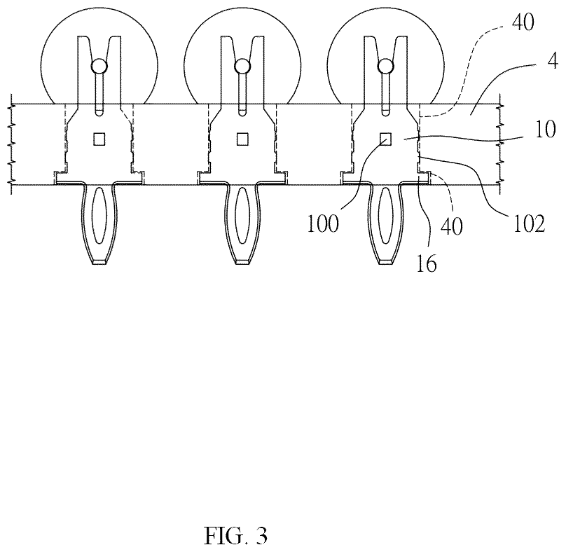

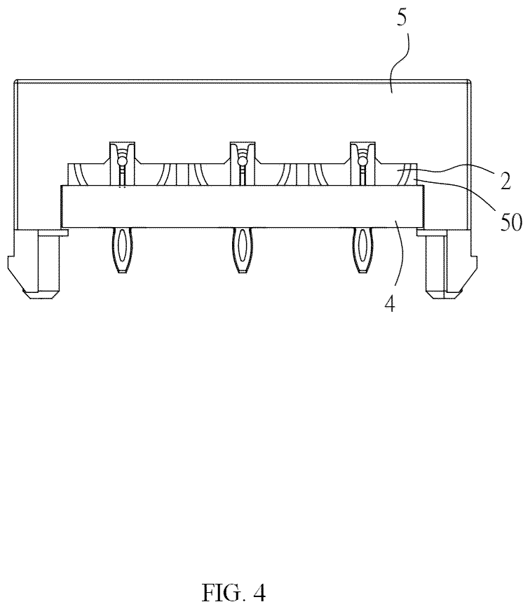

After the electronic element 2 is clamped by the terminal structure 1 as shown in FIG. 2, the terminal body 10 is inserted into one of the slots 40 of the fixture 4 as shown in FIG. 3. At this time, the interference means 102 and the locking means 100 are locked on the fixture 4, so that the terminal body 10 is locked and secured in one of the slots 40 of the fixture 4. In addition, the stop means 16 rests on the fixture 4 to limit the height position of the terminal body 10 after the terminal body 10 is inserted into one of the slots 40 of the fixture 4. Then, the fixture 4, the electronic element 2, and the terminal structure 1 are assembled in the housing 5 as shown in FIG. 4. At this time, the electronic element 2 is received in the mounting portion 50 of the housing 5, and the fixture 4 is locked in the mounting portion 50 of the housing 5.

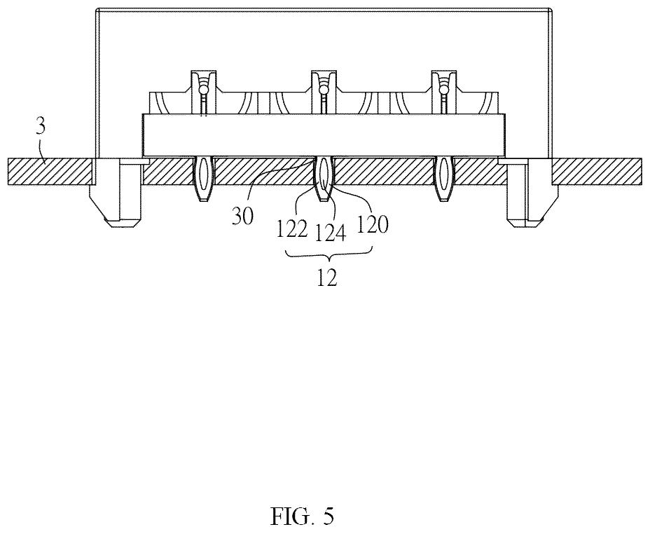

When the housing 5 is mounted on the circuit board 3, the insertion unit 12 of the terminal structure 1 is inserted into and locked in one of the conducting holes 30 of the circuit board 3 as shown in FIG. 5. At this time, each of the conducting holes 30 of the circuit board 3 has a width less than the maximum width of the insertion unit 12, so that when the insertion unit 12 is forced to be inserted into one of the conducting holes 30 of the circuit board 3, the first press side 120 and the second press side 122 are compressed and contracted toward the internal space 124. Thus, the first press side 120 and the second press side 122 closely contact with a conducting wall in one of the conducting holes 30, to achieve an electrically conducting function. In addition, the first press side 120 and the second press side 122 of the insertion unit 12 are secured in one of the conducting holes 30 exactly so that the insertion unit 12 is secured to the circuit board 3 steadily.

Accordingly, one of the lead legs 20 of the electronic element 2 is directly clamped and held by the holding mechanism 14 of the terminal structure 1, so that the terminal structure 1 is assembled with the electronic element 2 easily, quickly, and exactly. In addition, the terminal body 10 of the terminal structure 1 is directly locked and secured in one of the slots 40 of the fixture 4, so that the terminal structure 1 is assembled with the fixture 4 easily, quickly, and exactly. Further, the electronic element 2 is received in the mounting portion 50 of the housing 5, and the fixture 4 is locked in the mounting portion 50 of the housing 5, so that the fixture 4, the electronic element 2, and the terminal structure 1 are directly assembled with the housing 5. Further, the insertion unit 12 of the terminal structure 1 is directly inserted into and locked in one of the conducting holes 30 of the circuit board 3, so that the terminal structure 1 is assembled with the circuit board 3 easily, quickly, and exactly.

In conclusion, one of the lead legs 20 of the electronic element 2 is clamped in the clamping space 142 of the terminal structure 1. Then, the terminal body 10 of the terminal structure 1 is secured in one of the slots 40 of the fixture 4. Then, the electronic element 2 is mounted in the mounting portion 50 of the housing 5, and the fixture 4 is secured in the housing 5. In such a manner, the terminal structure 1 is in turn assembled with the electronic element 2, the fixture 4, and the housing 5, to construct a complete electronic appliance. Thus, the electronic appliance of the terminal structure 1, the electronic element 2, the fixture 4, and the housing 5 is directly mounted on the circuit board 3, to achieve a quick and exact assembly.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the scope of the invention.

1. A terminal structure comprising:
a terminal body;
a locking means formed on at least one face of the terminal body;
an insertion unit extending from a first end of the terminal body; and
a holding mechanism extending from a second end of the terminal body;
wherein:
the insertion unit is mounted on a circuit board;
the circuit board defines multiple conducting holes;
the insertion unit is inserted into and locked in one of the conducting holes of the circuit board;
the holding mechanism includes two opposite clamping arms and a clamping space defined between the two clamping arms;
an electronic element is held by the holding mechanism;
the electronic element has multiple lead legs; and
one of the lead legs of the electronic element is clamped between the two clamping arms and held in the clamping space.

2. The terminal structure as claimed in claim 1, wherein a stop means is defined between the terminal body and the insertion unit.

3. The terminal structure as claimed in claim 1, wherein the insertion unit includes a first press side, a second press side having two ends connecting two ends of the first press side, and an internal space defined between the first press side and the second press side.

4. The terminal structure as claimed in claim 1, wherein the terminal body has two opposite sides, and each of the two sides of the terminal body defines multiple interference means.

5. The terminal structure as claimed in claim 1, wherein:
each of the two clamping arms defines a first side wall and a second side wall;
the first side wall of each of the two clamping arms is located between the terminal body and a first end of the clamping space; and
the second side wall of each of the two clamping arms is situated at a second end of the clamping space.

6. The terminal structure as claimed in claim 5, wherein the first side walls of the two clamping arms are parallel with each other, with a constant distance defined between the first side walls of the two clamping arms.

7. The terminal structure as claimed in claim 5, wherein the second side walls of the two clamping arms gradually diverge forward from the clamping space.

8. The terminal structure as claimed in claim 4, wherein:
a fixture defines multiple slots;
the terminal body is inserted into one of the slots of the fixture; and
each of the interference means is locked in one of the slots of the fixture.

9. The terminal structure as claimed in claim 8, wherein:
a housing defines a mounting portion;
the terminal structure and the electronic element are assembled and received in the mounting portion of the housing after the terminal structure is locked on the electronic element; and
the fixture is secured in the mounting portion of the housing.
